(19) United States
(12) Patent Application Publication
(10) Pub. No.: US 2007/0243386 A1
(43) Pub. Date: Oct. 18, 2007

(54) Process for preparation of multi-thin layered structure

(76) Inventors: Hyun Jung Park, Yuseong-gu (KR); Ji-Weon Jeong, Cheonan-si (JP)

Correspondence Address: MCKENNA LONG & ALDRIDGE LLP, 1900 K STREET, NW, WASHINGTON, DC, 20006, US

(21) Appl. No.: 11/783,406

(22) Filed: Apr. 9, 2007

(30) Foreign Application Priority Data
Apr. 17, 2006 (KR) 10-2006-0034356

(51) Int. Cl. C23C 16/24; C23C 16/00; H05H 1/24; B32B 9/00

(52) U.S. Cl. 428/411.1; 427/255.393; 427/255.394; 427/578; 427/588

(57) ABSTRACT

Disclosed herein is a method of manufacturing multi-layered thin films having different physical properties on a base material using a plasma-enhanced chemical vapor deposition (PECVD) process. The method includes changing a plasma frequency to be applied, while not changing a composition ratio of a mixed gas for plasma generation, to sequentially form thin films corresponding to a plasma composition of the plasma frequency.

### FIELD OF THE INVENTION

The present invention relates to a method of manufacturing a multi-layered thin film structure based on a plasma-enhanced chemical vapor deposition (PECVD) process, and, more particularly, to a method of forming a multi-layered thin film structure including multi-layered thin films having different physical properties on a base material using a PECVD process wherein the method includes changing a plasma frequency (the number of vibrations) to be applied, while not changing a composition ratio of a mixed gas for plasma generation, to sequentially form thin films corresponding to a plasma composition of the plasma frequency.

### BACKGROUND OF THE INVENTION

In recent years, as concern about environmental pollution and energy exhaustion has increased, a solar battery has attracted considerable attention as an alternative energy source having abundant resources, no problems related to environmental pollution, and high energy efficiency.

The solar battery may be classified as a solar heat battery that generates steam necessary to rotate a turbine using solar heat or a photon battery that converts photons into electric energy using the properties of semiconductors. Especially, much research has been actively carried out on the photon battery, which absorbs light to generate electrons and holes, thereby converting photon energy into electric energy.

In the photon battery, the photoelectric conversion efficiency is controlled depending upon the amount of light absorbed into the photon battery. For this reason, it is very important to reduce the reflection of the light absorbed into the photon battery. Consequently, anti-reflection films are used to reduce the reflection of the light, or a method of minimizing the area screening the photons when forming electrode terminals is used. Especially, much research has been carried out on the anti-reflection films having low reflection.

Generally, anti-reflection films are preferably silicon nitride films constructed in a multi-layered structure. Specifically, when a second silicon nitride film having a relatively low refractive index is formed on a first silicon nitride film having a relatively high refractive index, it is possible to obtain high reflection prevention rate.

The silicon nitride films are generally formed by a PECVD process. In order to form silicon nitride films having a multi-layered structure, it is necessary to perform deposition while changing the mixed gas ratio of plasma. However, the atmosphere in a PECVD reaction chamber must be completely changed so as to change the mixed gas ratio of plasma. As a result, process time is increased, and raw material is wasted, and the composition uniformity of the thin films is deteriorated.

### SUMMARY OF THE INVENTION

Therefore, the present invention has been made to solve the above problems, and other technical problems that have yet to be resolved. Specifically, the present invention proposes a technology for manufacturing a multi-layered thin film structure including two or more thin films having the same components as anti-reflection films of the solar battery but different compositions by changing only a plasma frequency while maintaining the gas atmosphere in a reaction chamber, thereby remarkably reducing time necessary for manufacturing the multi-layered thin film structure.

Methods of changing a plasma frequency in a PECVD process to obtain a desired effect have been proposed; however, these methods do not teach or suggest the application to a method of forming a multi-layered thin film structure as in the present invention.

For example, Japanese Patent Registration No. 3286951 discloses a technology for supplying high-frequency power by modulation periods of 50 to 100 KHz at a duty ratio of 95 to 40% when forming films and changing the high-frequency power, such that the high-frequency power can be supplied at a duty ratio of 80 to 100%, when cleaning the interior of a vacuum chamber, thereby performing plasma cleaning with etching gas introduced into the vacuum chamber.

Also, Japanese Patent Registration No. 2820070 discloses a technology for using plasma generated by applying high-frequency voltage periodically changed between a plurality of frequencies to a raw material so as to improve the step coverage of thin films and fine aluminum wiring embedding property, thereby modifying a thin film formed when the frequency of the applied high-frequency voltage is large into the same thin film as a thin film formed when the frequency of the applied high-frequency voltage is small.

However, the above-mentioned patents provide a technology for removing films or powders accumulated at tray electrodes, a shower plate, and a reflector when thin films are formed on a plurality of substrates or changing the plasma frequency when forming and modifying thin films so as to obtain thin films having excellent physical properties. In other words, the patents do not provide a technology for changing the plasma frequency in forming a multi-layered thin film structure comprising two or more thin films having the same components but different compositions as in the present invention.

In accordance with the present invention, the above and other objects can be accomplished by the provision of a method of forming a multi-layered thin film structure including multi-layered thin films having different physical properties on a base material using a plasma-enhanced chemical vapor deposition (PECVD) process, wherein the method includes changing a plasma frequency (the number of vibrations) to be applied, while not changing a composition ratio of a mixed gas for plasma generation, to sequentially form thin films corresponding to a plasma composition of the plasma frequency.

When the applied plasma frequency is changed although the gases are the same mixed gas for plasma generation, the ionization ratio of the mixed gas is changed. In the method according to the present invention, only the plasma frequency is changed to sequentially grow thin films having different compositions on the base material in consideration of the above description.

According to the present invention, therefore, it is possible to easily manufacture a multi-layered thin film structure having desired physical properties by selectively changing only the plasma frequency while not changing the component ratio of the mixed gas for plasma generation. Consequently, the manufacturing process according to the present invention is greatly simplified as compared with the conventional art in which the chamber atmosphere must be renewed to form such a multi-layered thin film structure, and the waste of raw material is minimized.

Changing the plasma frequency in a PECVD reaction chamber may be realized in various manners. In a preferred embodiment, two or more generators that supplies different frequencies are included in an apparatus for performing the PECVD process, and the plasma frequency is changed by the selective operation of the generators. According to circumstances, the plasma composition may be decided by changing the plasma frequency application time of the generators by predetermined periods.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view illustrating a shower-head type plate electrode plasma-enhanced chemical vapor deposition (PECVD) apparatus according to a preferred embodiment of the present invention; and

FIG. 2 is a graph illustrating experimental results of Example 1 according to the present invention.

### DETAILED DESCRIPTION OF PREFERRED EMBODIMENTS

Now, a preferred embodiment of the present invention will be described in detail with reference to the accompanying drawings.

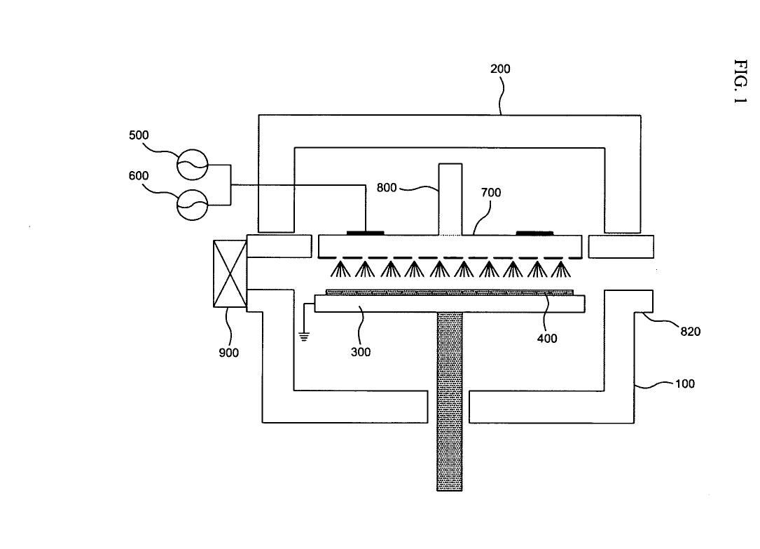

FIG. 1 is a view illustrating a shower-head type plate electrode plasma-enhanced chemical vapor deposition (PECVD) apparatus according to a preferred embodiment of the present invention.

Referring to FIG. 1, a reaction chamber 100, which is open at the top thereof, is covered by a chamber cover 200 such that a reaction space isolated from the outside is defined by the reaction chamber 100 and the chamber cover 200. In the reaction space is mounted a susceptor 300, which can be moved upward and downward, and is electrically grounded. On the susceptor 300 is located a substrate 400. In the susceptor 300 is mounted a heater for heating the substrate 400.

In the reaction space above the susceptor 300 is mounted a shower-head type plate electrode 700, which is connected to two different external radio frequency (RF) generators 500 and 600. One of the RF generators, i.e., a first RF generator 500, supplies a relatively high frequency, whereas the other RF generator, i.e., a second RF generator 600, supplies a relatively low frequency. The interior of the plate electrode 700 is hollow. A gas injection pipe 800 communicates with the interior of the plate electrode 700. In the bottom of the plate electrode 700 are formed spraying holes 720 having a small diameter. The plate electrode 700 is made of a metal material, and the surface of the plate electrode 700 is anodized such that arc is prevented from being generated due to plasma.

A mixed gas for plasma generation injected from the gas injection pipe 800 is ionized by the plate electrode 700, is deposited on the substrate 400, and is discharged through a gas discharge pipe 820. In the course of ionization, a thin film is deposited on the substrate 400 using a mixed gas ionized by the high-frequency RF generator, i.e., the first RF generator 500, and another thin film is deposited on the substrate 400 using a mixed gas ionized by the low-frequency RF generator, i.e., the second RF generator 600. The thin film deposited using the mixed gas ionized by the first RF generator 500 has a different composition from the thin film deposited using the mixed gas ionized by the second RF generator 600. The operations of the RF generators 500 and 600 may be sequentially performed or repetitively performed at regular time intervals.

At a side wall of the reaction chamber 100 is mounted a slot valve 900 which allows or prohibits the communication between a loadlock unit (not shown) and the reaction space. The slot valve 900 is opened when the substrate 400 is transferred to the loadlock unit to the susceptor 300.

In the present invention, the base material is not particularly restricted so long as a multi-layered thin film structure is formed on the base material using a PECVD process. For example, the base material may be a silicon wafer used for manufacturing semiconductors, a glass substrate used for manufacturing thin film transistors (TFTs), or a silicon wafer used for manufacturing solar batteries. According to circumstances, one or more thin films may have already been formed on the base material, or a predetermined dopant may have already been implanted in the base material so as to partially or entirely activate the base material.

The thin films manufactured by the above-described method are ones having the same components but different compositions (different components ratios). For example, multi-layered silicon nitride films, which are used as anti-reflection films for solar batteries, may be manufactured. However, the thin films manufactured by the above-described process are not limited to the multi-layered silicon nitride films. The silicon nitride films, as anti-reflection films, are constructed in a structure in which a lower-layer thin film having a high refractive index and an upper-layer thin film having a low refractive index are sequentially stacked on a silicon wafer. The lower-layer thin film and the upper-layer thin film have Si and N as components. When the composition of the lower-layer thin film and the upper-layer thin film, i.e., the component ratio of the lower-layer thin film and the upper-layer thin film, is changed, however, the lower-layer thin film and the upper-layer thin film have different refractive indexes (physical properties).

According to a preferred embodiment, therefore, the base material is a silicon wafer used for manufacturing solar batteries, and the multi-layered thin films are multi-layered anti-reflection films having different refractive indexes.

When a silicon nitride thin film is formed on a silicon wafer using a PECVD process, a mixed gas including, for example, SiH₄ and NH₃, as a reaction gas, may be supplied into the reaction chamber of the PECVD apparatus as shown in FIG. 1 so as to perform chemical deposition. Generally, the reaction chamber of the PECVD apparatus is filled with an inert gas, as an atmospheric gas. Preferably, the inert gas is N₂ or Ar.

In a preferred embodiment, a 5 to 50 MHz generator, as the high-frequency generator, and a 10 to 500 KHz generator, as the low-frequency generator, are mounted in the PECVD chamber to form the multi-layered silicon nitride thin films. The high-frequency generator and the low-frequency generator are sequentially operated to manufacture multi-layered thin films having different refractive indexes. According to circumstances, the high-frequency generator and the low-frequency generator may be alternately operated at time intervals of 1 to 60 seconds so as to adjust the refractive index of the thin films.

The present invention provides an electronic device including the multi-layered thin film structure manufactured by the above-described method. A representative example of such an electronic device may be a solar battery module including anti-reflection films constructed in a multi-layered thin film structure.

The construction of the solar battery module including the anti-reflection films constructed in the multi-layered thin film structure and a method of manufacturing the solar battery module are well known in the art to which the present invention pertains, and therefore, a detailed description thereof will not be given.

Hereinafter, examples of the present invention will be described in detail. It should be noted, however, that the scope of the present invention is not limited by the illustrated examples.

First, a high-frequency generator having a frequency of 13.56 MHz, as a first RF generator, and a low-frequency generator having a frequency of 10 to 500 KHz, as a second RF generator, were mounted in a PECVD apparatus as shown in FIG. 1. In this experiment, the frequency applied by the second RF generator was approximately 450 KHz. Also, process conditions were set, as indicated in Table 1 below, so as to deposit multi-layered silicon nitride thin films on a silicon wafer.

TABLE 1

| | |
|---|---|
| Plasma frequency | 13.56 MHz & 450 KHz |
| Plasma power | 20 W |
| Deposition pressure | 1.2 torr |
| Deposition temperature | 350° C. |
| Total gas flow rate | 900 sccm |
| (N₂ + SiH₄ + NH₃) | |
| Reaction gas | SiH₄, NH₃ |
| Atmospheric gas | N₂ |

### EXAMPLE 1

Silicon nitride thin films were deposited on a silicon wafer while the component ratio of a reaction gas (mixed gas) including SiH₄ and NH₃ (NH₃/SiH₄) was changed within a range of 0.6 to 2.0 under the condition that only the first RF generator was operated so as to apply a frequency of 13.56 MHz, and the refractive index of the deposited silicon nitride thin films were measured.

Also, silicon nitride thin films were deposited in the same manner as the above under the condition that only the second RF generator was operated so as to apply a frequency of 450 KHz, and the refractive indexes of the deposited silicon nitride thin films were measured.

Also, silicon nitride thin films were deposited in the same manner as the above under the condition that the first RF generator and the second RF generator were alternately operated at approximately 10-second intervals so as to alternately apply frequencies of 13.56 MHz and 450 KHz, and the refractive indexes of the deposited silicon nitride thin films were measured.

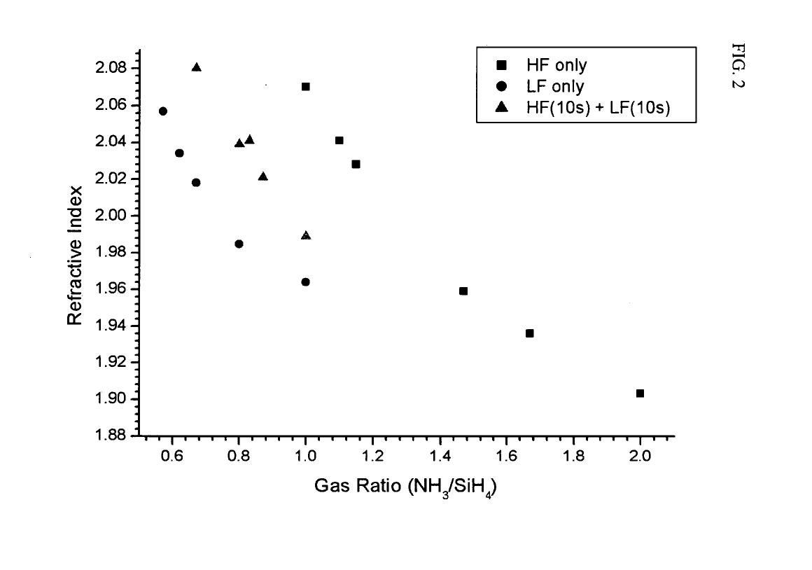

The measurement results are shown in FIG. 2. As can be seen from FIG. 2, there were obtained silicon nitride thin films having different refractive indexes depending upon the applied plasma frequencies as well as the composition ratio of the reaction gas. When the first RF generator is operated in a reaction gas composition ratio (NH₃/SiH₄) of 1.0, for example, a silicon nitride thin film was obtained having a refractive index of 2.07. When the second RF generator is operated, a silicon nitride thin film was obtained having a refractive index of 1.96. When the first RF generator and the second RF generator are alternately operated, a silicon nitride thin film was obtained having a refractive index of 1.99.

### EXAMPLE 2

Anti-reflection films, which are constructed in a structure in which a silicon nitride thin film having a low refractive index is stacked on a silicon nitride thin film having a high refractive index, were formed on a silicon wafer as follows. The first RF generator was operated for 90 seconds in a reaction gas composition ratio (NH₃/SiH₄) of 1.0 under the same process conditions as Table 1 above to deposit a silicon nitride thin film having a refractive index of 2.07 to a thickness of 40 nm. After a rest for 1 or 2 seconds, the second RF generator was operated for 98 seconds to deposit a silicon nitride thin film having a refractive index of 1.96 to a thickness of 40 nm. In this way, anti-reflection films constructed in a multi-layered structure were manufactured.

### COMPARATIVE EXAMPLE 1

Anti-reflection films, which are constructed in a structure in which a silicon nitride thin film having a low refractive index is stacked on a silicon nitride thin film having a high refractive index, were formed on a silicon wafer as follows. The first RF generator was operated for 90 seconds in a reaction gas composition ratio (NH₃/SiH₄) of 1.0 under the same process conditions as Table 1 above to deposit a silicon nitride thin film having a refractive index of 2.07 to a thickness of 40 nm. After that, the introduction of the reaction gas was interrupted, and only the atmospheric gas was introduced for 60 seconds to renew the atmosphere in the chamber. Subsequently, the reaction gas is introduced into the chamber in a reaction gas composition ratio (NH₃/SiH₄) of 1.5, and the second RF generator was operated for 98 seconds to deposit a silicon nitride thin film having a refractive index of 1.96 to a thickness of 40 nm. In this way, anti-reflection films constructed in a multi-layered structure were manufactured.

### [Results Analysis]

The comparison between Example 2 and Comparative Example 1 reveals that, when the anti-reflection films having the same multi-layered structure were formed on the silicon wafers, only 1 or 2 seconds were required to change the applied frequencies in Example 2 according to the present invention, whereas at least one or two minutes were required to renew the atmosphere in the chamber and to redeposit the thin film in Comparative Example 1. Consequently, there was great difference in total process time between Example 2 and Comparative Example 1.

Furthermore, in Comparative Example 1, a large amount of reaction gas was inevitably wasted during the renewal of the atmosphere in the chamber, and the uniformity of the refractive index of the silicon nitride thin film was low as compared with the multi-layered thin film structure manufactured in Example 1.

### INDUSTRIAL APPLICABILITY

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

As apparent from the above description, it is possible to form a multi-layered thin film structure having the same components but different compositions by changing only the plasma frequency through a continuous process. Consequently, the present invention has the effect of reducing the total process time, reducing the loss of raw material, reducing the manufacturing costs, and improving the uniformity and physical properties of the multi-layered thin film structure.

This application claims priority to Korean Application 10-2006-0034356 filed on Apr. 17, 2006, which is incorporated by referecne, as if fully set forth herein.

What is claimed is:

1. A method of forming multi-layered thin films having different physical properties on a base material using a plasma-enhanced chemical vapor deposition (PECVD) process, wherein the method comprises:
changing a plasma frequency to be applied, while not changing a composition ratio of a mixed gas for plasma generation, to sequentially form thin films corresponding to a plasma composition of the plasma frequency.

2. The method according to claim 1, wherein two or more generators that supplies different frequencies are included in an apparatus for performing the PECVD process, and the plasma frequency is changed by the selective operation of the generators.

3. The method according to claim 2, wherein the plasma composition is decided by changing the plasma frequency application time of the generators by predetermined periods.

4. The method according to claim 1, wherein the base material is a silicon wafer used for manufacturing semiconductors, a glass substrate used for manufacturing thin film transistors (TFTs), or a silicon wafer used for manufacturing solar batteries.

5. The method according to claim 1, wherein the base material is a silicon wafer used for manufacturing solar batteries, and the multi-layered thin films are multi-layered anti-reflection films having different refractive indexes.

6. The method according to claim 5, wherein the Anti-reflection films are silicon nitride thin films.

7. The method according to claim 6, wherein the silicon nitride thin films are formed by supplying a mixed gas including SiH₄ and NH₃ and an atmospheric gas of N₂ or Ar into a reaction chamber of an apparatus for performing the PECVD process.

8. The method according to claim 7, wherein a 5 to 50 MHz generator, as a high-frequency generator, and a 10 to 500 KHz generator, as a low-frequency generator, are mounted in the apparatus for performing the PECVD process, and the high-frequency generator and the low-frequency generator are sequentially operated to change the plasma composition.

9. The method according to claim 8, wherein the high-frequency generator and the low-frequency generator are alternately operated at time intervals of 1 to 60 seconds so as to form silicon nitride thin films having predetermined refractive indexes.

10. A solar battery module comprising anti-reflection films having a multi-layered thin film structure manufactured by the method according to claim 1.
